(19) United States
(12) Patent Application Publication
(10) Pub. No.: US 2024/0032389 A1
(43) Pub. Date: Jan. 25, 2024

(54) OLED DISPLAY PANEL AND OLED DISPLAY DEVICE

(71) Applicants: Huizhou China Star Optoelectronics Display Co., Ltd., Huizhou (CN); Shenzhen China Star Optoelectronics Semiconductor Display Technology Co., Ltd., Shenzhen (CN)

(72) Inventor: Zhijun Wan, Huizhou (CN)

(21) Appl. No.: 17/620,101

(22) PCT Filed: Nov. 30, 2021
(86) PCT No.: PCT/CN2021/134262

§ 371 Date: May 25, 2023

(30) Foreign Application Priority Data
Nov. 18, 2021 (CN) 202111366939.6
Nov. 18, 2021 (CN) 2021113669396

(51) Int. Cl. H10K 59/80; H10K 59/35

(52) U.S. Cl. CPC H10K 59/873; H10K 59/352; H10K 59/879; H10K 2102/351

(57) ABSTRACT

The present application provides an OLED display panel and an OLED display device; in the OLED display panel, a thickness of part of an organic layer located in a middle area of a display area is greater than a thickness of part of the organic layer located in an edge area of the display area to reduce an optical path difference between the middle area and the edge area of the display area, and the problem of optical path difference of light in different directions of the OLED display device is alleviated or even eliminated.

### FIELD OF THE INVENTION

The present application relates to a display technology field, and more particularly to an OLED display panel and an OLED display device.

### BACKGROUND OF THE INVENTION

OLED (Organic Light-Emitting Diode) display devices are widely used due to the advantages of self-luminescence and flexibility. The top-emitting OLED display device possesses advantages over the bottom-emitting OLED display device because it does not affect the circuit design, and possesses a lower operating voltage at the same brightness, longer device life and lower power consumption. In OLED display devices, there are two problems: one is that when light is emitted, part of the light with a large incident angle will be totally reflected and cannot be emitted, resulting in a decrease in light output efficiency, and the other is that top-emitting OLED display devices possess a strong microcavity effect. The light emitted from different directions leads to different microcavity effects due to different optical paths, which can easily produce chromatic aberration and cause poor brightness. Even if the light extraction layer is disposed on the OLED device in the prior art, the light extraction layer can only solve the problem of decreased light output efficiency, and cannot solve the technical problems of chromatic aberration and uneven brightness.

Therefore, the existing OLED display device has a technical problem of uneven brightness of the OLED display device caused by the different optical paths of the light in different directions.

### SUMMARY OF THE INVENTION

The embodiment of the present application provides an OLED display panel and an OLED display device, so as to alleviate the technical problem of uneven brightness of the OLED display device caused by the different optical paths of the light in different directions in the existing OLED display device.

To solve the aforesaid problem, the technical solution of the present application is described as follows:

The embodiment of the present application provides an OLED display panel, comprising:
a substrate;
a driving circuit layer arranged on one side of the substrate;
a light emitting function layer arranged on one side of the driving circuit layer away from the substrate;
an encapsulation layer arranged on one side of the light emitting function layer away from the driving circuit layer;
wherein the OLED display panel comprises a display area and a non-display area, and the encapsulation layer comprises an organic layer, and a thickness of part of the organic layer located in a middle area of the display area is greater than a thickness of part of the organic layer located in an edge area of the display area.

In some embodiments, the thickness of the organic layer progressively decreases from the middle area of the display area to the edge area of the display area.

In some embodiments, the display area comprises a light emitting area and a non-light emitting area, and a thickness of part of the organic layer located in the light emitting area is greater than a thickness of part of the organic layer located in the non-light emitting area.

In some embodiments, the thickness of part of the organic layer located in the middle area of the light emitting area is greater than a thickness of part of the organic layer located in an edge area of the light emitting area.

In some embodiments, the OLED display panel comprises a red sub-pixel, a green sub-pixel and a blue sub-pixel, and a shape of the organic layer at a corresponding position of the red sub-pixel is different from a shape of the organic layer at a corresponding position of the green sub-pixel, and the shape of the organic layer at the corresponding position of the green sub-pixel is different from a shape of the organic layer at a corresponding position of the blue sub-pixel.

In some embodiments, the encapsulation layer further comprises a first inorganic layer and a second inorganic layer, and the first inorganic layer is disposed between the organic layer and the light emitting function layer, and the second inorganic layer is disposed on one side of the organic layer away from the first inorganic layer, and a thickness of each area of the first inorganic layer is equal, and a thickness of each area of the second inorganic layer is equal.

In some embodiments, a surface of the organic layer in contact with the first inorganic layer is planar, and on one side of the organic layer in contact with the second inorganic layer, a height of the organic layer in the middle area of the light emitting area is greater than a height of the edge area of the light emitting area.

In some embodiments, the edge area comprises a first edge area and a second edge area located on both sides of the middle area, and a thickness of the organic layer progressively decreases from the middle area to the first edge area, and the thickness of the organic layer progressively decreases from the middle area to the second edge area.

In some embodiments, the edge area comprises a third edge area, a fourth edge area, a fifth edge area and a sixth edge area located around the middle area, and a thickness of the organic layer progressively decreases from the middle area to the third edge area, and the thickness of the organic layer progressively decreases from the middle area to the fourth edge area, and the thickness of the organic layer progressively decreases from the middle area to the fifth edge area, and the thickness of the organic layer progressively decreases from the middle area to the sixth edge area.

In some embodiments, a refractive index of the first inorganic layer is smaller than a refractive index of the organic layer, and the refractive index of the organic layer is smaller than a refractive index of the second inorganic layer.

In some embodiments, the OLED display panel further comprises a protective film, and the protective film is disposed on one side of the second inorganic layer away from the organic layer, and a thickness of part of the protective layer located in the middle area of the light emitting area is smaller than a thickness of part of the protective layer located in the edge area of the light emitting area, and the thickness of part of the protective layer located in the edge area of the light emitting area is smaller than a thickness of part of the protective layer located in the non-display area.

In some embodiments, the OLED display panel further comprises a protective film, and the protective film is disposed on one side of the second inorganic layer away from the organic layer, and a thickness of each area of the protective film is equal.

In some embodiments, the encapsulation layer further comprises a first inorganic layer and a second inorganic layer, and the first inorganic layer is disposed between the organic layer and the light emitting function layer, and the second inorganic layer is disposed on one side of the organic layer away from the first inorganic layer, and a thickness of each area of the first inorganic layer is equal, and a thickness of part of the second inorganic layer located in the middle area of the light emitting area is smaller than a thickness of part of the second inorganic layer located in the edge area of the light emitting area, and the thickness of part of the second inorganic layer located in the edge area of the light emitting area is smaller than a thickness of part of the second inorganic layer located in the non-light emitting area.

Meanwhile, the embodiment of the present application provides an OLED display device. The OLED display device comprises an OLED display panel and an electronic component. The OLED display panel comprises:
a substrate;
a driving circuit layer arranged on one side of the substrate;
a light emitting function layer arranged on one side of the driving circuit layer away from the substrate;
an encapsulation layer arranged on one side of the light emitting function layer away from the driving circuit layer;
wherein the OLED display panel comprises a display area and a non-display area, and the encapsulation layer comprises an organic layer, and a thickness of part of the organic layer located in a middle area of the display area is greater than a thickness of part of the organic layer located in an edge area of the display area.

In some embodiments, the thickness of the organic layer progressively decreases from the middle area of the display area to the edge area of the display area.

In some embodiments, the display area comprises a light emitting area and a non-light emitting area, and a thickness of part of the organic layer located in the light emitting area is greater than a thickness of part of the organic layer located in the non-light emitting area.

In some embodiments, the thickness of part of the organic layer located in the middle area of the light emitting area is greater than a thickness of part of the organic layer located in an edge area of the light emitting area.

In some embodiments, the OLED display panel comprises a red sub-pixel, a green sub-pixel and a blue sub-pixel, and a shape of the organic layer at a corresponding position of the red sub-pixel is different from a shape of the organic layer at a corresponding position of the green sub-pixel, and the shape of the organic layer at the corresponding position of the green sub-pixel is different from a shape of the organic layer at a corresponding position of the blue sub-pixel.

In some embodiments, the encapsulation layer further comprises a first inorganic layer and a second inorganic layer, and the first inorganic layer is disposed between the organic layer and the light emitting function layer, and the second inorganic layer is disposed on one side of the organic layer away from the first inorganic layer, and a thickness of each area of the first inorganic layer is equal, and a thickness of each area of the second inorganic layer is equal.

In some embodiments, a surface of the organic layer in contact with the first inorganic layer is planar, and on one side of the organic layer in contact with the second inorganic layer, a height of the organic layer in the middle area of the light emitting area is greater than a height of the edge area of the light emitting area.

In some embodiments, the edge area comprises a first edge area and a second edge area located on both sides of the middle area, and a thickness of the organic layer progressively decreases from the middle area to the first edge area, and the thickness of the organic layer progressively decreases from the middle area to the second edge area.

The present application provides an OLED display panel and an OLED display device; the OLED display panel comprises a substrate, a driving circuit layer, a light emitting function layer and an encapsulation layer, and the driving circuit layer is arranged on one side of the substrate, and the light emitting function layer is arranged on one side of the driving circuit layer away from the substrate, and the encapsulation layer is arranged on one side of the light emitting function layer away from the driving circuit layer, wherein the OLED display panel comprises a display area and a non-display area, and the encapsulation layer comprises an organic layer, and a thickness of part of the organic layer located in a middle area of the display area is greater than a thickness of part of the organic layer located in an edge area of the display area. In the present application, the organic layer in the encapsulation layer is designed so that the thickness of part of the organic layer located in the middle area of the display area is greater than the thickness of part of the organic layer located in the edge area of the display area, thus, there is no need of the light extraction layer. The light output efficiency is improved through the organic layer, and the thickness of the OLED display panel is reduced. Meanwhile, by changing the thickness of the organic layer, the difference between the optical path in the middle area of the display area and the optical path in the edge area of the display area is reduced. It alleviates or even eliminates the problem of different optical paths of the light in the different directions of the OLED display device, to reduce or even eliminate the chromatic aberration in different directions for avoiding the problem of uneven brightness.

### BRIEF DESCRIPTION OF THE DRAWINGS

The technical solution and the beneficial effects of the present application are best understood from the following detailed description with reference to the accompanying figures and embodiments.

FIG. 1 is a first diagram of an OLED display panel provided by an embodiment of the application.

FIG. 2 is a second diagram of an OLED display panel provided by an embodiment of the application.

FIG. 3 is a third diagram of an OLED display panel provided by an embodiment of the application.

FIG. 4 is a first diagram of a light emitting area provided by an embodiment of the application.

FIG. 5 is a second diagram of a light emitting area provided by an embodiment of the application.

FIG. 6 is a diagram of an OLED display device provided by an embodiment of the application.

### DETAILED DESCRIPTION OF PREFERRED EMBODIMENTS

For better explaining the technical solution and the effect of the present invention, the present invention will be further described in detail with the accompanying drawings in the specific embodiments. It is clear that the described embodiments are merely part of embodiments of the present application, but not all embodiments. Based on the embodiments of the present application, all other embodiments to those of skilled in the premise of no creative efforts obtained, should be considered within the scope of protection of the present application.

The embodiment of the present application provides an OLED display panel and an OLED display device, so as to alleviate the technical problem of uneven brightness of the existing OLED display device caused by the different optical paths of the light in different directions in the existing OLED display device.

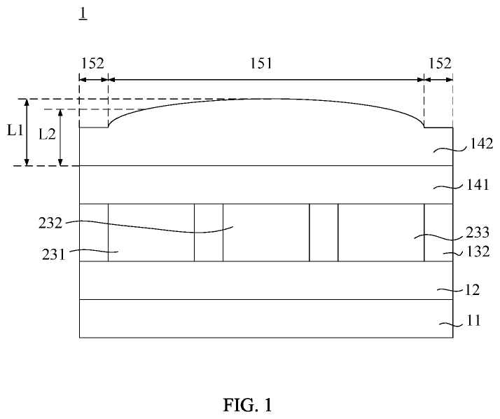

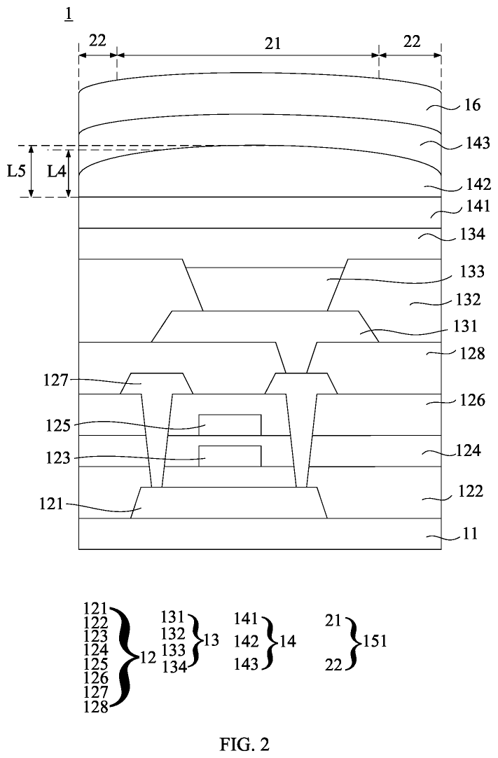

As shown in FIG. 1 and FIG. 2, the embodiment of the present application provides an OLED display panel. The OLED display panel 1 comprises:
a substrate 11;
a driving circuit layer 12 arranged on one side of the substrate 11;
a light emitting function layer 13 arranged on one side of the driving circuit layer 12 away from the substrate 11;
an encapsulation layer 14 arranged on one side of the light emitting function layer 13 away from the driving circuit layer 12;
wherein the OLED display panel 1 comprises a display area 151 and a non-display area 152, and the encapsulation layer 14 comprises an organic layer 142, and a thickness L1 of part of the organic layer 142 located in a middle area of the display area 151 is greater than a thickness L2 of part of the organic layer 142 located in an edge area of the display area 151.

The embodiment of the present application provides an OLED display panel. In the OLED display panel, the organic layer in the encapsulation layer is designed so that the thickness of part of the organic layer located in the middle area of the display area is greater than the thickness of part of the organic layer located in the edge area of the display area, thus, there is no need of the light extraction layer. The light output efficiency is improved through the organic layer, and the thickness of the OLED display panel is reduced. Meanwhile, by changing the thickness of the organic layer, the difference between the optical path in the middle area of the display area and the optical path in the edge area of the display area is reduced. It alleviates or even eliminates the problem of different optical paths of the light in the different directions of the OLED display device, to reduce or even eliminate the chromatic aberration in different directions for avoiding the problem of uneven brightness.

Specifically, in the embodiments of the present application, the middle area and the edge area refer to the general definition of area division. For instance, the display area can be divided into three areas from the non-display area close to one side to the non-display area close to the other side, and the area between the two areas close to the non-display area is the middle area, and the two areas close to the non-display area are the edge areas. As for whether the middle area and the edge area are equally divided, that is, whether the area of the middle area and each edge area are equal, it is not limited here. For instance, the display area is divided into three areas from left to right. The middle area may have the same area as the edge areas on both sides, but the area of the middle area may also be larger than the area of the edge areas on both sides.

Specifically, the thickness of the organic layer progressively decreases from the middle area of the display area to the non-display area. That is, by decreasing the thickness of the organic layer from the middle area to the non-display area, the difference between the optical path of the light emitted from the large viewing angle (after passing through multiple layers, light may be emitted from the edge of the non-display area, so the large viewing angle comprises the edge area of the display area and also comprises the non-display area) and the optical path of the light in the middle area is reduced to avoid the problem of uneven brightness caused by the optical path difference of light in different directions.

Specifically, as determining the edge area of the display area, regarding that large-size display devices is mainly caused by the excessive difference between the optical paths of the light on the left and right sides and the optical path of the light in the middle area, resulting in problems of uneven brightness and color difference of the display device. Therefore, the organic layer can be designed as a curved surface extending from the middle area to both sides, thereby reducing the optical path difference of light in different directions and reducing chromatic aberration; for small-sized display devices, the optical path difference between the optical path of the surrounding light and the optical path of the middle area will cause the problem of obvious chromatic aberration. Therefore, the organic layer can be designed as a spherical surface extending from the middle area to the surroundings, so that the optical path difference between the optical path of the light around the OLED display device and the optical path of the light in the middle area of the OLED display device is reduced to alleviate uneven brightness and reduce chromatic aberration.

Specifically, for the design of the non-display area, the non-display area can be a curved surface with the same arc as the display area, or the non-display area can be planar but the thickness of the non-display area is made smaller than the thickness of the display area, thereby reducing optical path difference of light in different directions.

In one embodiment, as shown in FIG. 1, the thickness of the organic layer 142 progressively decreases from the middle area of the display area 151 to the edge area of the display area 151. Thus, the display area of the display panel can be made to appear as a curved surface, so that the thickness of the organic layer decreases from the middle area to the edge area, thereby improving the color difference and uneven brightness of the display device.

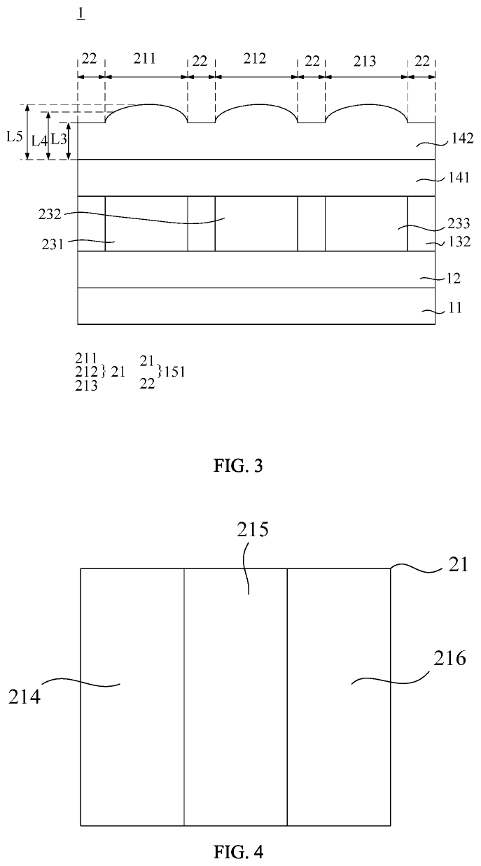

only designing the organic layer for the entire surface still possesses the problem of optical path difference of light in different directions of a single pixel or a single sub-pixel. In one embodiment, as shown in FIG. 3, the display area 151 comprises a light emitting area 21 and a non-light emitting area 22, and a thickness L5 of part of the organic layer 142 located in the light emitting area 21 is greater than a thickness L3 of part of the organic layer 142 located in the non-light emitting area 22. By designing the light emitting area and the non-light emitting area, the thickness of the organic layer in the light emitting area is greater than that in the non-light emitting area. The optical path difference of light in different directions in respective light emitting areas can be reduced, and the optical path difference of light in different directions of respective light emitting areas can be avoided to cause color shift of respective light emitting pixels or light emitting sub-pixels, thereby improving the technical problems of color difference and uneven brightness of the display device.

Specifically, the foregoing embodiment is described in detail by taking the arrangement of the organic layers in the light emitting area and the non-light emitting area. The light emitting area generally refers to the light emitting area of the sub-pixel. Therefore, the arrangement of the pixel is not involved here, but the embodiment of the present application is not limited to this, and the arrangement of the pixel may also adopt the aforesaid arrangement. For instance, the thickness of the organic layer at the position of the corresponding pixel is made larger than the thickness of the organic layer at the position between the pixels, which will not be repeated here.

only designing the organic layer in the light emitting area and the non-light emitting area still possesses the problem of different optical path of light in different directions of a single sub-pixel. In one embodiment, as shown in FIG. 2, the thickness L5 of part of the organic layer 142 located in the middle area of the light emitting area 21 is greater than a thickness L4 of part of the organic layer 142 located in an edge area of the light emitting area 21. By making the thickness of part of the organic layer located in the middle area of the light emitting area is greater than the thickness of part of the organic layer located in the edge area of the light emitting area, the difference between the optical path of the light located in the middle area of the light emitting area and the light path of the light located in the edge area of the light emitting area is reduced. Thus, the brightness and the color of the light emitted from a single sub-pixel are the same at all angles, thereby avoiding the problem of uneven brightness or chromatic aberration.

It should be noted that the meaning of the middle area and the edge area in this embodiment can still adopt the specific meanings in the explanation made in the foregoing embodiment, and will not be repeated here.

In one embodiment, as shown in FIG. 3, the OLED display panel 1 comprises a red sub-pixel 231, a green sub-pixel 232 and a blue sub-pixel 233, and a shape of the organic layer 142 at a corresponding position 211 of the red sub-pixel 231 is the same as a shape of the organic layer 142 at a corresponding position 212 of the green sub-pixel 232, and the shape of the organic layer 142 at the corresponding position 212 of the green sub-pixel 232 is the same as a shape of the organic layer 142 at a corresponding position 213 of the blue sub-pixel 233. As configuring the organic layer, the corresponding design is implemented for each light emitting sub-pixel, so that the organic layer of each light emitting sub-pixel can present a shape with a reduced thickness from the middle to the two sides, thereby improving the issues of the uneven brightness and the chromatic aberration of each light emitting sub-pixel.

Specifically, for convenience, in FIG. 3, the red light emitting device, the green light emitting device and the blue light emitting device refer to the red sub-pixel, the green sub-pixel and the blue sub-pixel, respectively. However, in practice, the red sub-pixel refers to all the film layers that can make the red light emitting device emit light, the green sub-pixel refers to all the film layers that can make the green light emitting device emit light, and the blue sub-pixel refers to all the film layers that can make the blue light emitting device emit light.

The aforesaid embodiment is described in detail by taking the same shape of sub-pixels of different colors as an illustration. However, in actual design, considering that in order to improve the light emitting life and resolution of some display devices, the light emitting sub-pixels of different colors will be designed with different shapes and different thicknesses. Therefore, the organic layer can be designed according to the light emitting sub-pixels of different colors.

In one embodiment, the OLED display panel comprises a red sub-pixel, a green sub-pixel and a blue sub-pixel, and a shape of the organic layer at a corresponding position of the red sub-pixel is different from a shape of the organic layer at a corresponding position of the green sub-pixel, and the shape of the organic layer at the corresponding position of the green sub-pixel is different from a shape of the organic layer at a corresponding position of the blue sub-pixel. Accordingly, for sub-pixels of different shapes and sizes, corresponding designs can be implemented to correspondingly improve the brightness unevenness and color difference of different sub-pixels.

In one embodiment, as shown in FIG. 2, the encapsulation layer 14 further comprises a first inorganic layer 141 and a second inorganic layer 143, and the first inorganic layer 141 is disposed between the organic layer 142 and the light emitting function layer 13, and the second inorganic layer 143 is disposed on one side of the organic layer 142 away from the first inorganic layer 141, and a thickness of each area of the first inorganic layer 141 is equal, and a thickness of each area of the second inorganic layer 143 is equal. As configuring the encapsulation layer for the arrangement of the first inorganic layer and the second inorganic layer, the processes of the first inorganic layer and the second inorganic layer are not changed. The first inorganic layer and the second inorganic layer are respectively formed on the light emitting function layer and the organic layer to reduce process difficulty. Therefore, the second inorganic layer will appear as a curved shape on the organic layer, and through this structure, the optical path difference of light in different directions is reduced, so as to avoid the problems of uneven brightness and chromatic aberration.

Specifically, a surface of the organic layer in contact with the first inorganic layer is planar, and on one side of the organic layer in contact with the second inorganic layer, a height of the organic layer in the middle area of the light emitting area is greater than a height of the edge area of the light emitting area. Namely, as configuring the first inorganic layer, the first inorganic layer is kept in a plane arrangement, and the organic layer is arranged with different heights at the side away from the first inorganic layer, so as to realize the different thickness arrangement of the organic layer in the different areas.

The aforesaid embodiment is described in detail by taking the contact surface of the first inorganic layer and the organic layer as a plane, but the embodiment of the present application is not limited to this. For instance, the surface of the first inorganic layer in contact with the organic layer is a curved surface, and a groove is formed by the first inorganic layer, and the organic layer forms protrusions. Meanwhile, the organic layer is formed as a curved surface on the side away from the first inorganic layer to realize that the thickness of the organic layer in the middle area of the light emitting area is greater than the thickness in the edge area of the light emitting area, and also greater than the thickness in the non-light emitting area.

Regarding that when light is emitted from the light emitting area, the optical path of the light decreases gradually from the middle area of the light emitting area to the edge area of the light emitting area, and the thickness of the organic layer can be gradually reduced by configuring the organic layer as a curved surface, thereby improving the uneven brightness and chromatic aberration caused by the optical path difference of light in different directions.

In one embodiment, as shown in FIG. 3 and FIG. 4, the edge area comprises a first edge area 214 and a second edge area 216 located on both sides of the middle area 215, and a thickness of the organic layer 142 progressively decreases from the middle area 215 to the first edge area 214, and the thickness of the organic layer 142 progressively decreases from the middle area 215 to the second edge area 216. Regarding the uneven brightness and chromatic aberration, which is mainly caused by the optical path difference of the light on both sides and the light in the middle area, by progressively decreasing the thickness of the organic layer from the middle area to the edge areas on both sides, the optical path of the light progressively decreases from the middle area to the edge areas on both sides. The optical path difference of light in different directions can be reduced to avoid the problems of uneven brightness and chromatic aberration.

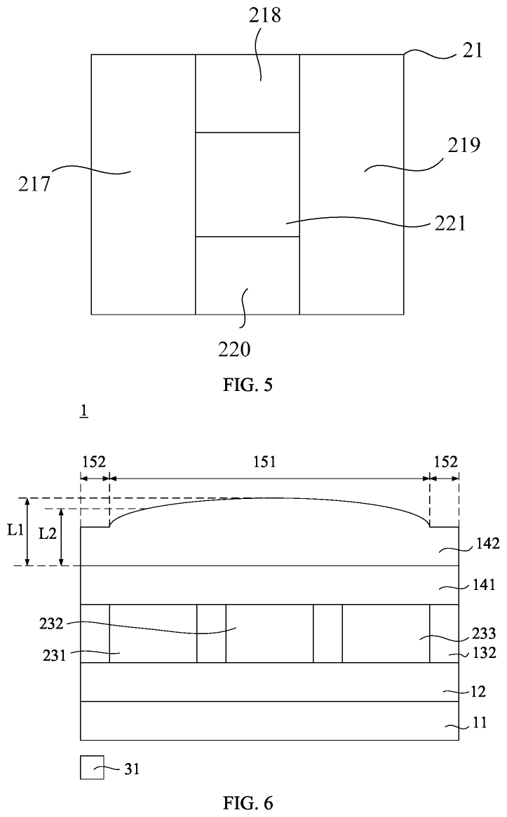

In one embodiment, as shown in FIG. 3 and FIG. 5, the edge area comprises a third edge area 217, a fourth edge area 218, a fifth edge area 219 and a sixth edge area 220 located around the middle area 221, and a thickness of the organic layer 142 progressively decreases from the middle area 221 to the third edge area 217, and the thickness of the organic layer 142 progressively decreases from the middle area 221 to the fourth edge area 218, and the thickness of the organic layer 142 progressively decreases from the middle area 221 to the fifth edge area 219, and the thickness of the organic layer 142 progressively decreases from the middle area 221 to the sixth edge area 220. Regarding the uneven brightness and chromatic aberration, which is mainly caused by the optical path difference of the light around the light emitting area and the light in the middle area, by progressively decreasing the thickness of the organic layer from the middle area to the edge areas in the surroundings, the optical path of the light progressively decreases from the middle area to the edge areas in the surroundings. The optical path difference of light in different directions can be reduced to avoid the problems of uneven brightness and chromatic aberration.

In one embodiment, a refractive index of the first inorganic layer is smaller than a refractive index of the organic layer, and the refractive index of the organic layer is smaller than a refractive index of the second inorganic layer. The refractive index from the first inorganic layer to the second inorganic layer is increased gradually, thereby increasing the light transmittance.

In one embodiment, as shown in FIG. 2, the OLED display panel 1 further comprises a protective film 16, and the protective film 16 is disposed on one side of the second inorganic layer 143 away from the organic layer 142. With the protective film, the encapsulation layer is protected and the intrusion of water and oxygen is blocked.

In one embodiment, the OLED display panel further comprises a protective film, and the protective film is disposed on one side of the second inorganic layer away from the organic layer, and a thickness of each area of the protective film is equal. As configuring the protective film, the thickness of the protective film can be kept consistent. However, since the product will be covered by protective glass when it is accomplished, the unevenness of the OLED display panel can be eliminated. Thus, the surface of the protective film of the OLED display panel can be arranged to be uneven.

Different thicknesses of different areas of the organic layer in the encapsulation layer will cause the problem of unevenness of the OLED display device. In one embodiment, the OLED display panel further comprises a protective film, and the protective film is disposed on one side of the second inorganic layer away from the organic layer, and a thickness of part of the protective layer located in the middle area of the light emitting area is smaller than a thickness of part of the protective layer located in the edge area of the light emitting area, and the thickness of part of the protective layer located in the edge area of the light emitting area is smaller than a thickness of part of the protective layer located in the non-display area. By correspondingly designing the thickness of the protective layer in accordance with the arrangement of the organic layer, the thickness of part of the protective layer located in the middle area of the light emitting area is reduced, or the thickness of part of the protective layer in the edge area of the light emitting area is increased, so that the thicknesses of the protective layer in the different areas and the thicknesses of the organic layer in the corresponding areas have opposite configurations, and thus the OLED display panel can be kept planar after the protective film is provided.

In one embodiment, a surface of the protective film on the side away from the second inorganic layer is planar. That is, as configuring the protective film, the protective film is formed on the second inorganic layer. By configuring the side of the protective film away from the second inorganic layer as a plane, after the protective film is formed, the OLED display panel has a planar surface.

When the protective film is not provided, the uniform thickness of the second inorganic layer will cause the problem of unevenness of the OLED display panel. In one embodiment, the encapsulation layer further comprises a first inorganic layer and a second inorganic layer, and the first inorganic layer is disposed between the organic layer and the light emitting function layer, and the second inorganic layer is disposed on one side of the organic layer away from the first inorganic layer, and a thickness of each area of the first inorganic layer is equal, and a thickness of part of the second inorganic layer located in the middle area of the light emitting area is smaller than a thickness of part of the second inorganic layer located in the edge area of the light emitting area, and the thickness of part of the second inorganic layer located in the edge area of the light emitting area is smaller than a thickness of part of the second inorganic layer located in the non-light emitting area. By reducing the thickness of part of the second inorganic layer located in the middle area of the light emitting area, or increasing the thickness of part of the second inorganic layer located in the edge area of the light emitting area, the second inorganic layer can reduce the arc or even eliminate the arc, so that the second inorganic layer remains planar, and then the OLED display panel appears to be planar.

Specifically, the surface of the second inorganic layer away from the organic layer is planar. By configuring the second inorganic layer to be planar, the OLED display panel remains to be planar.

In the OLED display panel provided by the embodiment of the present application, regarding that the existing OLED display panel provided with the light extraction layer cannot solve the problems of uneven brightness and chromatic aberration caused by the optical path difference of light in different directions, by designing the organic layer to replace the light extraction layer with the organic layer, the problem of uneven brightness and chromatic aberration caused by the optical path difference of light in different directions can be solved at the same time. Compared with the OLED display panel in which the thickness of the light extraction layer in the different areas is configured to be different to solve the uneven brightness and chromatic aberration caused by the optical path difference of light in different directions, since the organic layer is designed in the present application, it reduces the thickness of the OLED display panel.

The aforesaid embodiment is described in detail by taking the encapsulation layer structure as the first inorganic layer, the organic layer and the second inorganic layer as an illustration. However, the embodiment of the present application is not limited to this. For instance, the encapsulation layer structure in some OLED display panels is a multilayer structure of inorganic layer/organic layer/inorganic layer/organic layer/inorganic layer. The multilayer organic layer can be designed accordingly, and the inorganic layer can be designed accordingly. The design is specifically conducted based on reducing the optical path difference of light in different directions, which will not be repeated here.

In one embodiment, the transmittance of the organic layer is greater than 90%, and the refractive index of the organic layer is greater than 1.7.

In one embodiment, the material of the organic layer comprises at least one of acrylic resin and epoxy resin.

In one embodiment, in order to realize the design of the organic layer in the present application, the organic layer can be formed by coating or inkjet printing. Specifically, after the film is formed by coating or inkjet printing, it can be pre-cured after being heated or irradiated with ultraviolet light to increase the viscosity of the film after pre-curing. Then, the embossing process is implemented to realize the optical arc design of the organic layer, and finally the organic layer is formed by thermal curing or ultraviolet curing.

Specifically, the concentration of the resin or additives is adjusted, so that when the resin is coated or inkjet printed, the resin exhibits a low viscosity state. Specifically, the viscosity can be less than 50 centipas. sec. After the resin is pre-cured, the viscosity will rise to a higher viscosity before the embossing process. Specifically, the viscosity can be 40,000 to 200,000 centipas. sec. It can be easier to take out the resin during coating or inkjet printing. After pre-curing, the viscosity is increased to prevent the resin from shifting or falling off to improve the film-forming result.

Specifically, as forming the organic layer and for reducing the process difficulty, the radian design can extend to the non-light emitting area or the non-display area; in order to promote the improvement of the color difference and brightness unevenness, the corresponding radian can be designed for respective sub-pixels.

In one embodiment, as shown in FIG. 2, the driving circuit layer 12 comprises an active layer 121, a first gate insulating layer 122, a first metal layer 123, a second gate insulating layer 124, a second metal layer 125, an interlayer insulating layer 126, a source and drain layer 127 and a planarization layer 128.

In one embodiment, as shown in FIG. 2, the light emitting function layer 13 comprises a pixel electrode layer 131, a pixel definition layer 132, a light emitting material layer 133 and a common electrode layer 134.

Meanwhile, the embodiment of the present application provides an OLED display device. As shown in FIG. 2 and FIG. 6, the OLED display device comprises an OLED display panel and an electronic component 31. The OLED display panel comprises:
a substrate 11;
a driving circuit layer 12 arranged on one side of the substrate 11;
a light emitting function layer 13 arranged on one side of the driving circuit layer 12 away from the substrate 11;
an encapsulation layer 14 arranged on one side of the light emitting function layer 13 away from the driving circuit layer 12;
wherein the OLED display panel 1 comprises a display area 151 and a non-display area 152, and the encapsulation layer 14 comprises an organic layer 142, and a thickness L1 of part of the organic layer 142 located in a middle area of the display area 151 is greater than a thickness L2 of part of the organic layer 142 located in an edge area of the display area 151.

The embodiment of the present application provides an OLED display device. The OLED display device comprises an OLED display panel and an electronic component. In the OLED display panel, the organic layer in the encapsulation layer is designed so that the thickness of part of the organic layer located in the middle area of the display area is greater than the thickness of part of the organic layer located in the edge area of the display area, thus, there is no need of the light extraction layer. The light output efficiency is improved through the organic layer, and the thickness of the OLED display panel is reduced. Meanwhile, by changing the thickness of the organic layer, the difference between the optical path in the middle area of the display area and the optical path in the edge area of the display area is reduced. It alleviates or even eliminates the problem of different optical paths of the light in the different directions of the OLED display device, to reduce or even eliminate the chromatic aberration in different directions for avoiding the problem of uneven brightness.

In one embodiment, in the OLED display device, the thickness of the organic layer progressively decreases from the middle area of the display area to the edge area of the display area.

In one embodiment, in the OLED display device, the display area comprises a light emitting area and a non-light emitting area, and a thickness of part of the organic layer located in the light emitting area is greater than a thickness of part of the organic layer located in the non-light emitting area.

In one embodiment, in the OLED display device, the thickness of part of the organic layer located in the middle area of the light emitting area is greater than a thickness of part of the organic layer located in an edge area of the light emitting area.

In one embodiment, in the OLED display device, the OLED display panel comprises a red sub-pixel, a green sub-pixel and a blue sub-pixel, and a shape of the organic layer at a corresponding position of the red sub-pixel is different from a shape of the organic layer at a corresponding position of the green sub-pixel, and the shape of the organic layer at the corresponding position of the green sub-pixel is different from a shape of the organic layer at a corresponding position of the blue sub-pixel.

In one embodiment, in the OLED display device, the encapsulation layer further comprises a first inorganic layer and a second inorganic layer, and the first inorganic layer is disposed between the organic layer and the light emitting function layer, and the second inorganic layer is disposed on one side of the organic layer away from the first inorganic layer, and a thickness of each area of the first inorganic layer is equal, and a thickness of each area of the second inorganic layer is equal.

In one embodiment, in the OLED display device, a surface of the organic layer in contact with the first inorganic layer is planar, and on one side of the organic layer in contact with the second inorganic layer, a height of the organic layer in the middle area of the light emitting area is greater than a height of the edge area of the light emitting area.

In one embodiment, in the OLED display device, the edge area comprises a first edge area and a second edge area located on both sides of the middle area, and a thickness of the organic layer progressively decreases from the middle area to the first edge area, and the thickness of the organic layer progressively decreases from the middle area to the second edge area.

In one embodiment, in the OLED display device, the edge area comprises a third edge area, a fourth edge area, a fifth edge area and a sixth edge area located around the middle area, and a thickness of the organic layer progressively decreases from the middle area to the third edge area, and the thickness of the organic layer progressively decreases from the middle area to the fourth edge area, and the thickness of the organic layer progressively decreases from the middle area to the fifth edge area, and the thickness of the organic layer progressively decreases from the middle area to the sixth edge area.

It can be known according to the above embodiment:
the embodiment of the present application provides an OLED display panel and an OLED display device, and the OLED display panel comprises a substrate, a driving circuit layer, a light emitting function layer and an encapsulation layer, and the driving circuit layer is arranged on one side of the substrate, and the light emitting function layer is arranged on one side of the driving circuit layer away from the substrate, and the encapsulation layer is arranged on one side of the light emitting function layer away from the driving circuit layer, wherein the OLED display panel comprises a display area and a non-display area, and the encapsulation layer comprises an organic layer, and a thickness of part of the organic layer located in a middle area of the display area is greater than a thickness of part of the organic layer located in an edge area of the display area. In the present application, the organic layer in the encapsulation layer is designed so that the thickness of part of the organic layer located in the middle area of the display area is greater than the thickness of part of the organic layer located in the edge area of the display area, thus, there is no need of the light extraction layer. The light output efficiency is improved through the organic layer, and the thickness of the OLED display panel is reduced. Meanwhile, by changing the thickness of the organic layer, the difference between the optical path in the middle area of the display area and the optical path in the edge area of the display area is reduced. It alleviates or even eliminates the problem of different optical paths of the light in the different directions of the OLED display device, to reduce or even eliminate the chromatic aberration in different directions for avoiding the problem of uneven brightness.

In the foregoing embodiments, the description of the various embodiments have respective different emphases, and a part in some embodiment, which is not described in detail can be referred to the related description of other embodiments.

The OLED display panel and the OLED display device provided by the embodiments of the present application is described in detail as aforementioned, and the principles and implementations of the present application have been described with reference to specific illustrations. The description of the foregoing embodiments is merely for helping to understand the technical solutions of the present application and the core ideas thereof; those skilled in the art should understand that the technical solutions described in the foregoing embodiments may be modified, or some of the technical features may be equivalently replaced; and the modifications or replacements do not deviate from the spirit and scope of the technical solutions of the embodiments of the present application.

What is claimed is:

1. An OLED (organic light emitting diode) display panel, comprising:
a substrate;
a driving circuit layer arranged on one side of the substrate;
a light emitting function layer arranged on one side of the driving circuit layer away from the substrate;
an encapsulation layer arranged on one side of the light emitting function layer away from the driving circuit layer;
wherein the OLED display panel comprises a display area and a non-display area, and the encapsulation layer comprises an organic layer, and a thickness of part of the organic layer located in a middle area of the display area is greater than a thickness of part of the organic layer located in an edge area of the display area.

2. The OLED display panel according to claim 1, wherein the thickness of the organic layer progressively decreases from the middle area of the display area to the edge area of the display area.

3. The OLED display panel according to claim 1, wherein the display area comprises a light emitting area and a non-light emitting area, and a thickness of part of the organic layer located in the light emitting area is greater than a thickness of part of the organic layer located in the non-light emitting area.

4. The OLED display panel according to claim 3, wherein the thickness of part of the organic layer located in the middle area of the light emitting area is greater than a thickness of part of the organic layer located at an edge area of the light emitting area.

5. The OLED display panel according to claim 4, wherein the OLED display panel comprises a red sub-pixel, a green sub-pixel and a blue sub-pixel, and a shape of the organic layer at a corresponding position of the red sub-pixel is different from a shape of the organic layer at a corresponding position of the green sub-pixel, and the shape of the organic layer at the corresponding position of the green sub-pixel is different from a shape of the organic layer at a corresponding position of the blue sub-pixel.

6. The OLED display panel according to claim 4, wherein the encapsulation layer further comprises a first inorganic layer and a second inorganic layer, and the first inorganic layer is disposed between the organic layer and the light emitting function layer, and the second inorganic layer is disposed on one side of the organic layer away from the first inorganic layer, and a thickness of each area of the first inorganic layer is equal, and a thickness of each area of the second inorganic layer is equal.

7. The OLED display panel according to claim 6, wherein a surface of the organic layer in contact with the first inorganic layer is planar, and on one side of the organic layer in contact with the second inorganic layer, a height of the organic layer in the middle area of the light emitting area is greater than a height of the edge area of the light emitting area.

8. The OLED display panel according to claim 7, wherein the edge area comprises a first edge area and a second edge area located on both sides of the middle area, and a thickness of the organic layer progressively decreases from the middle area to the first edge area, and the thickness of the organic layer progressively decreases from the middle area to the second edge area.

9. The OLED display panel according to claim 7, wherein the edge area comprises a third edge area, a fourth edge area, a fifth edge area and a sixth edge area located around the middle area, and a thickness of the organic layer progressively decreases from the middle area to the third edge area, and the thickness of the organic layer progressively decreases from the middle area to the fourth edge area, and the thickness of the organic layer progressively decreases from the middle area to the fifth edge area, and the thickness of the organic layer progressively decreases from the middle area to the sixth edge area.

10. The OLED display panel according to claim 6, wherein a refractive index of the first inorganic layer is smaller than a refractive index of the organic layer, and the refractive index of the organic layer is smaller than a refractive index of the second inorganic layer.

11. The OLED display panel according to claim 10, wherein the OLED display panel further comprises a protective film, and the protective film is disposed on one side of the second inorganic layer away from the organic layer, and a thickness of each area of the protective film is equal.

12. The OLED display panel according to claim 4, wherein the encapsulation layer further comprises a first inorganic layer and a second inorganic layer, and the first inorganic layer is disposed between the organic layer and the light emitting function layer, and the second inorganic layer is disposed on one side of the organic layer away from the first inorganic layer, and a thickness of each area of the first inorganic layer is equal, and a thickness of part of the second inorganic layer located in the middle area of the light emitting area is smaller than a thickness of part of the second inorganic layer located at the edge area of the light emitting area, and the thickness of part of the second inorganic layer located at the edge area of the light emitting area is smaller than a thickness of part of the second inorganic layer located in the non-light emitting area.

13. An OLED (organic light emitting diode) display device, comprising an OLED display panel and an electronic component; wherein the OLED display panel comprises:
a substrate;
a driving circuit layer arranged on one side of the substrate;
a light emitting function layer arranged on one side of the driving circuit layer away from the substrate;
an encapsulation layer arranged on one side of the light emitting function layer away from the driving circuit layer;
wherein the OLED display panel comprises a display area and a non-display area, and the encapsulation layer comprises an organic layer, and a thickness of part of the organic layer located in a middle area of the display area is greater than a thickness of part of the organic layer located in an edge area of the display area.

14. The OLED display device according to claim 13, wherein the thickness of the organic layer progressively decreases from the middle area of the display area to the edge area of the display area.

15. The OLED display device according to claim 13, wherein the display area comprises a light emitting area and a non-light emitting area, and a thickness of part of the organic layer located in the light emitting area is greater than a thickness of part of the organic layer located in the non-light emitting area.

16. The OLED display device according to claim 15, wherein the thickness of part of the organic layer located in the middle area of the light emitting area is greater than a thickness of part of the organic layer located at an edge area of the light emitting area.

17. The OLED display device according to claim 16, wherein the OLED display panel comprises a red sub-pixel, a green sub-pixel and a blue sub-pixel, and a shape of the organic layer at a corresponding position of the red sub-pixel is different from a shape of the organic layer at a corresponding position of the green sub-pixel, and the shape of the organic layer at the corresponding position of the green sub-pixel is different from a shape of the organic layer at a corresponding position of the blue sub-pixel.

18. The OLED display device according to claim 16, wherein the encapsulation layer further comprises a first inorganic layer and a second inorganic layer, and the first inorganic layer is disposed between the organic layer and the light emitting function layer, and the second inorganic layer is disposed on one side of the organic layer away from the first inorganic layer, and a thickness of each area of the first inorganic layer is equal, and a thickness of each area of the second inorganic layer is equal.

19. The OLED display device according to claim 18, wherein a surface of the organic layer in contact with the first inorganic layer is planar, and on one side of the organic layer in contact with the second inorganic layer, a height of the organic layer in the middle area of the light emitting area is greater than a height of the edge area of the light emitting area.

20. The OLED display device according to claim 19, wherein the edge area comprises a first edge area and a second edge area located on both sides of the middle area, and a thickness of the organic layer progressively decreases from the middle area to the first edge area, and the thickness of the organic layer progressively decreases from the middle area to the second edge area.
